(19) United States
(12) Patent Application Publication
(10) Pub. No.: US 2009/0134504 A1
(43) Pub. Date: May 28, 2009

(54) Semiconductor package and packaging method for balancing top and bottom mold flows from window

(75) Inventors: Kuo-Yuan Lee, Kaohsiung (TW); Yung-Hsiang Chen, Kaohsiung (TW)

Correspondence Address: Joe McKinney Muncy, PO Box 1364, Fairfax, VA, 22038-1364, US

(73) Assignee: Walton Advanced Engineering, Inc.

(21) Appl. No.: 11/987,229

(22) Filed: Nov. 28, 2007

(51) Int. Cl. H01L 23/13; H01L 21/56

(52) U.S. Cl. 257/680; 438/116; 257/E23.004; 257/E21.502

(57) ABSTRACT

A window-type semiconductor package to balance top and bottom moldflows and its method are revealed. The package primarily comprises a substrate having a slot, a chip, and an encapsulant. After die attaching, an input opening and an output opening are formed and exposed from both ends of the slot. The slot is off-center designed so that the dimension of the input opening is smaller than the one of the output opening. The encapsulant has a top molding portion formed on the top surface of the substrate and a smaller bottom molding portion formed on the bottom surface of the substrate. The mold-flowing speeds between the top molding portion and the bottom molding portion are balanced to eliminate trapped air bubbles in the top mold and to avoid the flooding of the molding compound in the bottom mold.

### FIELD OF THE INVENTION

The present invention relates to a window-type semiconductor packaging technology, especially to a window-type semiconductor package to balance the mold-flowing speeds above and below the substrate and its method.

### BACKGROUND OF THE INVENTION

Window Ball Grid Array, WBGA, package is one of the semiconductor packages using a substrate having a slot to carry and electrically connect an IC chip. For the existing transfer molding technologies, a WBGA package before encapsulation is placed inside a mold chest where molding compound is injected into the mold chest and cured to encapsulate the internal components of the WBGA package such as the chip and the electrical connecting components. However, since the molding dimension above the substrate is larger than the one below the substrate during molding leading to different mold-flowing speeds above the substrate and below the substrate. Because of different mold-flowing speeds, the faster mold-flowing speed will cause flooding of molding compound below the substrate and the slower mold-flowing speed will cause trapped air bubbles or voids in the encapsulant above the substrate.

As shown in FIG. 1, a conventional WBGA package 100 primarily comprises a substrate 110, a chip 120, a plurality of electrical connecting components 130 such as bonding wires, and an encapsulant 140. The substrate 110 has a top surface 111, a bottom surface 112, and a slot 113 penetrating the top surface 111 and the bottom surface 112. As shown in FIG. 2, the top surface 111 of the substrate 110 includes a die-attaching area 114 with a die-attaching material 116 disposed on the top surface 111 to firmly attach the chip 120 to the substrate 110. A plurality of external pads 115 are disposed on the bottom surface 112, as shown in FIG. 1. As shown in FIG. 2, an input opening 113A and an output opening 113B are formed on both ends of the slot 113 outside the die-attaching area 114. As shown in FIG. 1 and FIG. 2, the active surface 121 of the chip 120 is face-downward attached to the die-attaching area 114 with the input openings 113A and the output openings 113B exposed. A plurality of bonding pads 123 are formed on the active surface 121 of the chip 120. A plurality of electrical connecting components 130 electrically connect the bonding pads 123 to the substrate 110 by passing through the slot 113. The encapsulant 140 has a top molding portion 141 and a bottom molding portion 142 where the top molding portion 141 is formed on the top surface 111 to encapsulate the chip 120 and the bottom molding portion 142 is formed on the partial bottom surface 112 and inside the slot 113 to encapsulate the electrical connecting components 130. A plurality of external terminals 150 are disposed on the external pads 115 of the substrate 110 as external electrical connections to a printed circuit board, not shown in the figure. In a conventional WBGA package, the center of the slot 113 is aligned with the center of the substrate 110 as well as at the center of the chip 120 so that the input opening 113A and the output opening 113B have the same opening dimensions.

As shown in FIG. 1 and FIG. 3, during forming the encapsulant 140, the substrate 110 is disposed between a top molding tool 10 and a bottom molding tool 20. The molding compound is injected into the top mold chest (over the top surface 111 of the substrate 110) to form the top molding portion 141 and then flows into the bottom mold chest (on the partial bottom surface 112 of the substrate 110 and in the slot 113) through the input opening 113A to form the bottom molding portion 142. As shown in FIG. 1 and FIG. 3, since the dimension of the bottom mold chest for the bottom molding portion 142 is smaller than the one of the top mold chest for the top molding portion 141 so that the bottom mold-flowing speed 142A in the bottom mold chest is faster than the top mold-flowing speed 141A in the top mold chest. The molding compound will completely fill the bottom mold chest first and arrive at the output opening 113B earlier than the molding compound flowing in the top mold chest, therefore, the molding compound from the bottom mold chest will flow through the output opening 113B then flow into the top mold chest until the top mold chest is completely filled with the molding compound. The different filling time between the top mold chest and the bottom mold chest will cause the bottom molding portion 142 to flood on the bottom surface 112 of the substrate 110 to form bleeding 142B as shown in FIG. 1, and, all the worst, to cover the external pads 115 leading to poor electrical connections of the external terminals 150. Moreover, the bottom molding portion 142 will flow into the top mold chest through the output opening 113B and will interference with the flowing of the top molding portion 141 affecting the purge of air inside the top mold chest causing trapped air bubbles 141B in the top molding portion 141, as shown in FIG. 1, leading to poor reliability of the WBGA package.

### SUMMARY OF THE INVENTION

The main purpose of the present invention is to provide a window-type semiconductor package to balance the mold-flowing speeds above and below the substrate and its method by shifting the slot off the center of the substrate to form an input opening with a smaller dimension, to reduce the mold-flowing speed of the bottom flow, to balance the mold-flowing speeds in the top mold chest and in the bottom mold chest to avoid the flooding of the molding compound and to eliminate trapped air bubbles.

The second purpose of the present invention is to provide a window-type semiconductor package to balance the mold-flowing speeds above and below the substrate and its method to prevent flooding of the molding compound and to avoid contamination of the substrate by the molding compound. According to the present invention, a window-type semiconductor package primarily comprises a substrate, a chip, a plurality of electrical connecting components, and an encapsulant. The substrate has a top surface, a bottom surface, and at least a slot. The top surface includes a die-attaching area and a top molding area surrounding the die-attaching area and the slot. The bottom surface includes a bottom molding area surrounding the slot. Both ends of the slot are located outside the die-attaching area as an input opening and an output opening respectively, moreover, the dimension of the input opening is smaller than the one of the output opening. The chip is attached to the die-attaching area and is partially covered the slot with the input opening and the output opening exposed. The chip is electrically connected to the substrate by the electrical connecting components through the slot. The encapsulant has a top molding portion and a bottom molding portion where the top molding portion is formed on the top molding area and the bottom molding portion inside the bottom molding area and inside the slot so that the top and bottom molding portions are connected at the input opening and at the output opening and the volume of the top molding portion is larger than the one of the bottom molding portion. The manufacture method of the above mentioned window-type semiconductor package is also revealed.

### DESCRIPTION OF THE DRAWINGS

FIG. 1 shows a cross-sectional view of a conventional WBGA package across a substrate slot.

FIG. 2 shows a top view of the top surface of the substrate of the conventional WBGA package.

FIG. 3 shows a cross-sectional view of the conventional WBGA package along the substrate slot during molding.

FIG. 4 shows a cross-sectional view of a WBGA package across a substrate slot according to the preferred embodiment of the present invention.

FIG. 5 shows a top view of the top surface of the substrate of the WBGA package according to the preferred embodiment of the present invention.

FIG. 6 shows a top view of the bottom surface of the substrate of the WBGA package before molding according to the preferred embodiment of the present invention.

FIG. 7 shows a top view of the top surface of the substrate of the WBGA package before molding according to the preferred embodiment of the present invention.

FIG. 8 shows a cross-sectional view of the substrate of the WBGA package along the substrate slot during molding.

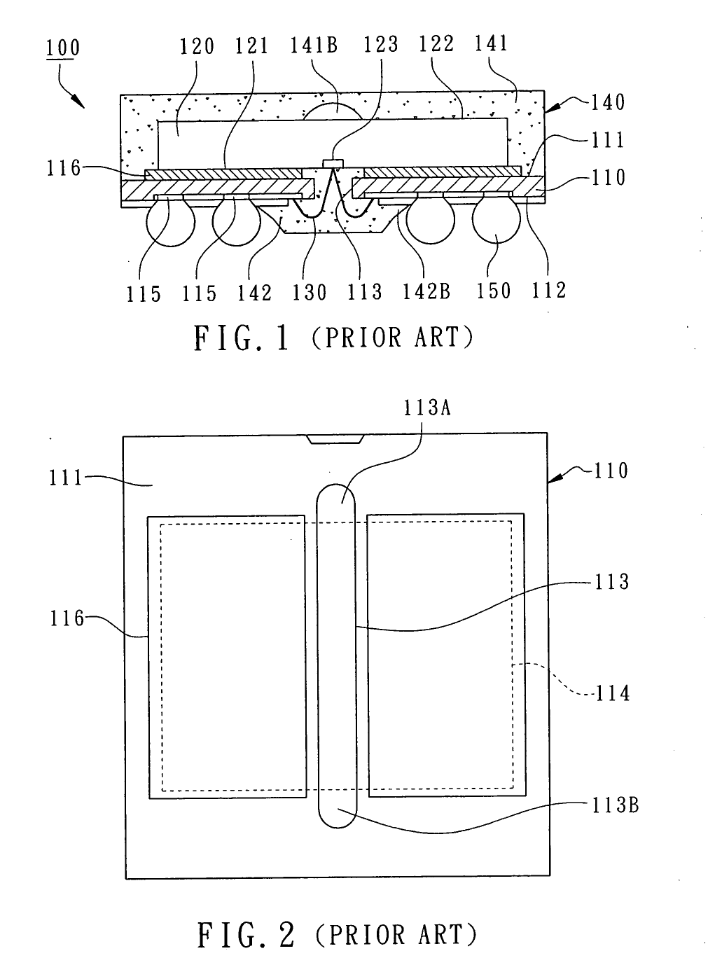

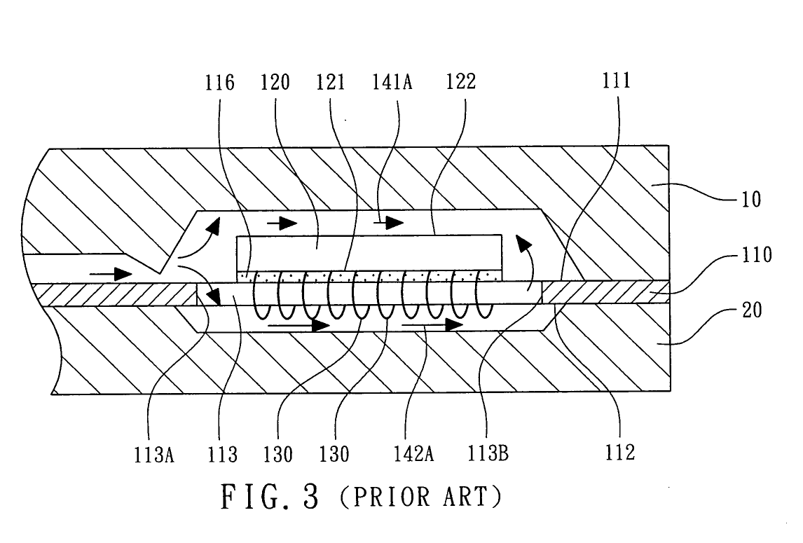

### DETAIL DESCRIPTION OF THE INVENTION

Please refer to the attached drawings, the present invention will be described by means of embodiment(s) below.

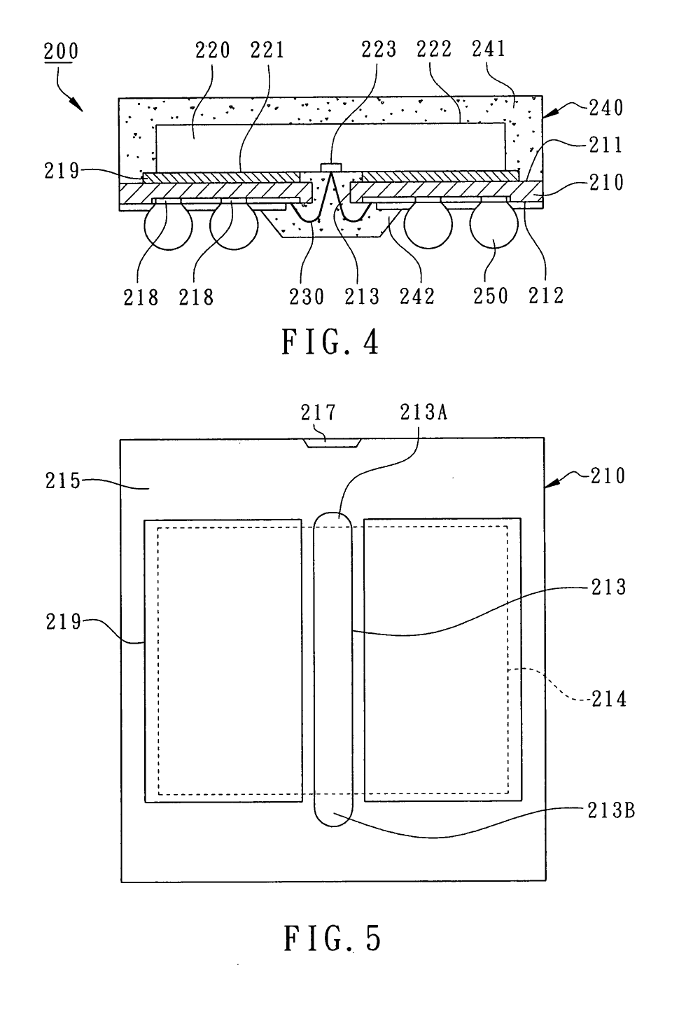

As shown in FIG. 4, a window-type semiconductor package 200 primarily comprises a substrate 210, a chip 220, a plurality of electrical connecting components 230, and an encapsulant 240. The substrate 210 has a top surface 211, a corresponding bottom surface 212, and at least a slot 213 where the slot 213 is long and narrow and penetrates the top surface 211 to the bottom surface 212. The substrate 210 acts as a chip carrier and has a single-layer or multi-layer traces such as printed circuit boards.

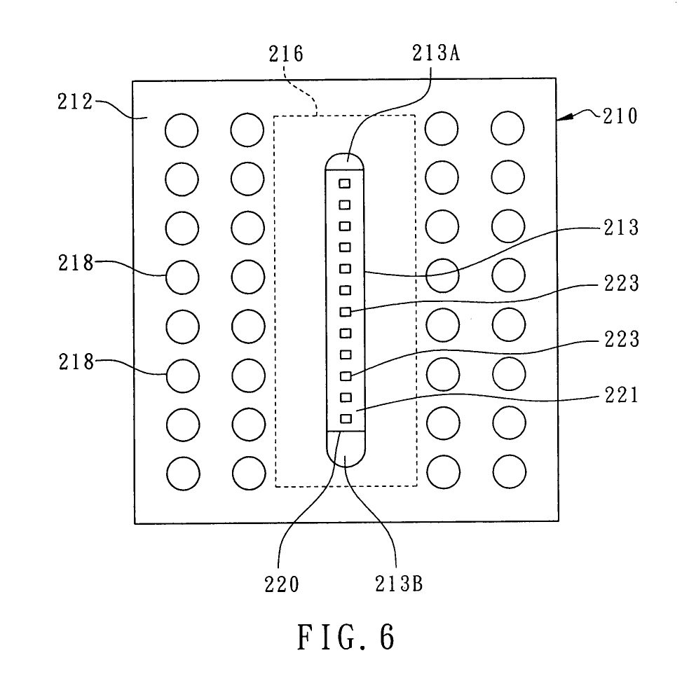

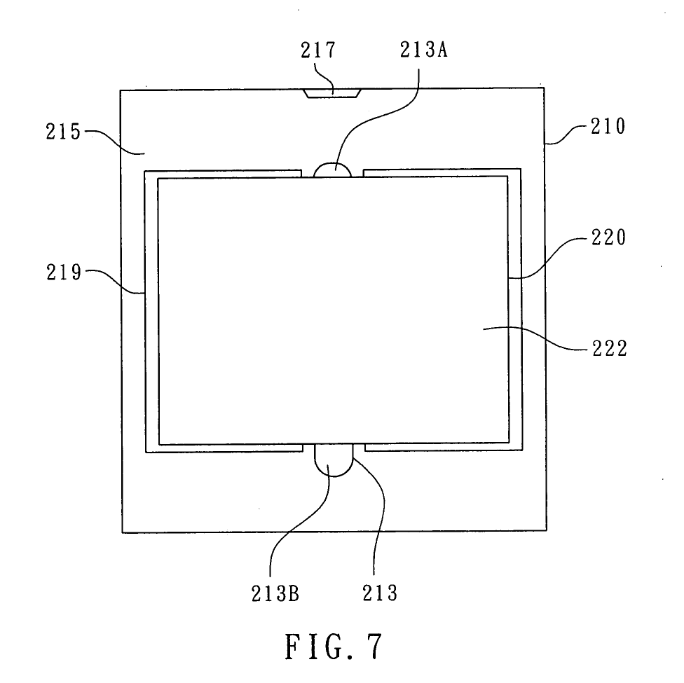

As shown in FIG. 4 and FIG. 5, the top surface 211 of the substrate 210 includes a die-attaching area 214 and a top molding area 215 to surround the die-attaching area 214 and the slot 213. The die-attaching area 214 is defined by the footprint of the chip 220 attached on the top surface 211 of the substrate 210. The top molding area 215 is an encapsulated area of the encapsulant 240 formed on the top surface 211 of the substrate 210 where the dimension of the top molding area 215 can be the same or slightly smaller than the one of the top surface 210 of the substrate 210. As shown in FIG. 5, both ends of the slot 213 are located outside the die-attaching area 214 as an input opening 213A and an output opening 213B for molding compounds respectively. As shown in FIG. 7, the chip 220 is attached to the top surface 211 of the substrate 210 and partially covers the slot 213 with the input opening 213A and the output opening 213B exposed so that the encapsulant 240 can flow through the input opening 213A and the output opening 213B. As shown in FIG. 5 again, the slot 213 is off-center designed so that the center of the slot 213 is not aligned with the center of the die-attaching area 214 (the chip 220) so that the dimension of the input opening 213A is smaller than the one of the output opening 213B. In this embodiment, the center of the die-attaching area 214 is aligned with the center of the substrate 210. As shown in FIG. 4 and FIG. 6, the bottom surface 212 includes a bottom molding area 216 to surround the slot 213 which is an encapsulating area of the encapsulant 240 formed on the bottom surface 212 of the substrate 210.

As shown in FIG. 4 and FIG. 5, a die-attaching material 219 is disposed on the top surface 211 of the substrate 210 to firmly attach the chip 220 where the die-attaching material 219 can be slightly larger than the die-attaching area 214 as shown in FIG. 5. In the present embodiment, a molding gate 217 is formed on the top surface 211 of the substrate 210 adjacent to the input opening 213A. The molding gate 217 is an exposed metal film for easily de-gating. In different embodiments, the molding gates 217 can be disposed at other locations on the substrate strip outside the substrate 210, not shown in figures. As shown in FIG. 6, the substrate 210 has a plurality of external pads 218 disposed on the bottom surface 212 and outside the bottom molding area 216 where the external pads 218 can be arranged in multiple rows or in an array.

The chip 220 has an active surface 221 and a corresponding back surface 222 with a plurality of bonding pads 223 formed on the active surface 221 as the external terminals for the internal circuits of IC. As shown in FIG. 4 and FIG. 7, the active surface 221 of the chip 220 is face-downward attached to the die-attaching area 214 of the substrate 210 by the die-attaching material 219 with the bonding pads 223 aligned and exposed from the slot 213. Moreover, the chip 220 is partially covered the slot 213 with the input opening 213A and the output opening 213B exposed. Since the center of the slot 213 is not aligned with the center of the chip 220, the dimension of the input opening 213A is smaller than the one of the output opening 213B. As shown in FIG. 7, in a more specific embodiment, the shape of the input opening 213A is an arc equal or smaller than a half-circle and the shape of the output opening 213B includes a half-circle for molding compound to flow in and out.

As shown in FIG. 4, the chip 220 is electrically connected to the substrate 210 by the electrical connecting components 230 passing through the slot 213. The electrical connecting components 230 can be bonding wires formed by wire-bonding technologies where one end of the bonding wire is bonded to the bonding pad 223 of the chip 220 and the other end of the bonding wire is bonded to the bonding finger on the bottom surface 212 of the substrate 210, not shown in the figure.

As shown in FIG. 4, the encapsulant 240 has a top molding portion 241 and a bottom molding portion 242 where the top molding portion 241 is formed on the top molding area 215 as shown in FIG. 5 and the bottom molding portion 242 on the bottom molding area 216 and inside the slot 213 as shown in FIG. 6 where the top molding portion 241 and the bottom molding portion 242 are connected at the input opening 213A and at the output opening 213B. Additionally, the volume of the top molding portion 241 is larger than the one of the bottom molding portion 242. The top molding portion 241 is formed on the top surface 211 of the substrate 210 to encapsulate the chip 220 and the bottom molding portion 242 is formed on the bottom surface 212 of the substrate 210 to encapsulate the electrical connecting components 230 and the slot 213 with less volume of molding compound than the one in the top molding portion 241.

To be more specific, the WBGA package 200 further comprises a plurality of external terminals 250 disposed on the external pads 218 as electrical terminals for the WBGA package to external devices such as a printed circuit board not shown in the figure. The external terminals 250 can be solder balls, solder paste, contact pads, or contact pins.

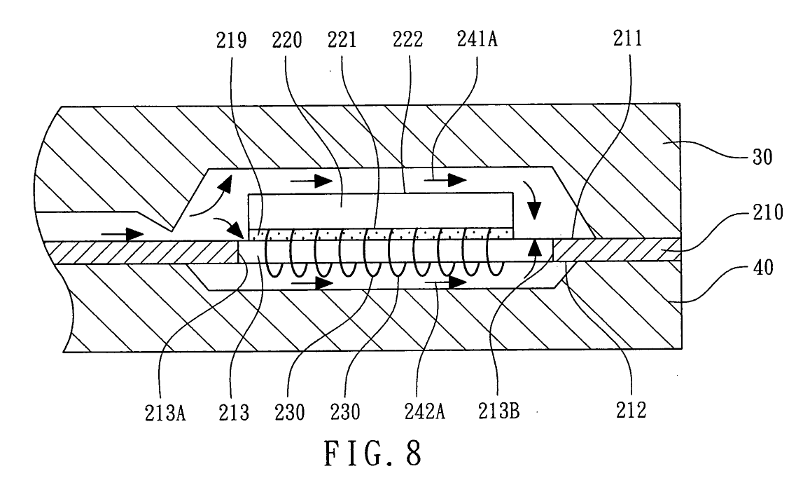

As shown in FIG. 4 and FIG. 8, during the formation of the encapsulant 240, the substrate 210 is clamped between a top molding tool 30 and a bottom molding tool 40 so that the chip 220 is disposed in the top mold chest of the top mold tool 30 and the slot 213 is aligned in the bottom mold chest of the bottom molding tool 40. The molding compound is injected into the top molding area 215 to form the top molding portion 241 and then flow through the input opening 213A to the bottom molding area.216 to form the bottom molding portion 242. The molding compound is then cured to form the encapsulant 240.

As shown in FIG. 6 and FIG. 7, the bottom mold-flowing speed 242A flowing in the bottom molding area 216 is reduced by the smaller dimension of the input opening 213A formed by off-center design of the slot 213 so that the bottom mold-flowing speed 242A is balanced with the top mold-flowing speed 241A as shown in FIG. 8. The top molding area 215 and the bottom molding area 216 are uniformly encapsulated without pin holes nor flooding as shown in FIG. 4 where the molding compound flowing in the bottom molding area 216 will arrive at the output opening 213B at the same time during molding without interfering the molding compound flowing in the top mold chest to avoid trapped air bubbles.

Furthermore, when the molding compound flows into the bottom mold chest of the bottom molding tool 40 through the input opening 213A, the bottom mold-flowing speed 242A is reduced due to the smaller dimension of the input opening 213A so that the molding compound filling time in the bottom mold chest is approximately equal to the one of the top mold chest. Therefore, the molding compound on the bottom molding area 216 will not flood into the gap between the bottom surface of the substrate 210 and the surface of the bottom molding tool 40 and the contamination of the external pads 218 due to the flooding of the molding compound is eliminated so that the poor electrical connections between the external pads 218 of the substrate and the external terminals are greatly improved and the reliability and the electrical connections of the WBGA package 200 are enhanced.

The manufacture method of the above mentioned FBGA 200 is also revealed in the present invention. Initially, a substrate 210 is provided by PCB processes, which has a top surface 211, a bottom surface 212, and at least a slot 213 where an input opening 213A and an output opening 213B are formed on both ends of the slot 213 outside the die-attaching area 214. The dimension of the input opening 213A is smaller than the output opening 213B.

Then, the chip 220 is attached to the substrate 210 by the die-attaching material 219, where the active surface 221 of the chip 220 is face-downward attached to the die-attaching area 214 with the input opening 213A and the output opening 213B exposed and the bonding pads 223 of the chip 220 are aligned within the slot 213. Then, by wire bonding, a plurality of electrical connecting components 230 such as bonding wires are formed through the slot 213 to electrically connect the bonding pads 223 of the chip 220 to the substrate 210.

Finally, an encapsulant 240 is formed over the top surface 211, inside the slot 213, and on the partial bottom surface 212, where the substrate 210 is clamped between the top molding tool 30 and the bottom molding tool 40 and the molding compound is injected into the top molding area 215 as shown in FIG. 4 and FIG. 8. The top molding portion 241 is formed in the top mold chest of the top molding tool 30 (on the top molding area 215) to encapsulate the chip 220 and the bottom molding portion 242 is formed in the bottom mold chest of the bottom molding tool 40 (on the bottom molding area 216 and inside the slot 213) to encapsulate the electrical connecting components 230 to form the top molding portion 241 and the bottom molding portion 242 respectively. The top molding portion 241 and the bottom molding portion 242 are connected at the input opening 213A and the output opening 213B and the volume of the top molding portion 241 is larger than the one of the bottom molding portion 242. The bottom mold-flowing speed 242A is reduced by using smaller input opening 213A, therefore, the bottom mold-flowing speed 242A is approximately equal to the top mold-flowing speed 241A so that the molding compound will arrive at the output opening 213B at the same time to avoid the flooding of the molding compound and to eliminate trapped air bubbles. Moreover, the encapsulant 240 will not flood to the external pads 218 and the WGBA package 200 will not be contaminated. The existing molding processes can be implemented without extra tooling costs nor extra processing steps.

The above description of embodiments of this invention is intended to be illustrative and not limiting. Other embodiments of this invention will be obvious to those skilled in the art in view of the above disclosure.

What is claimed:

1. A semiconductor package comprising:
a substrate having a top surface, a bottom surface, and at least a slot, wherein the top surface includes a die-attaching area and a top molding area surrounding the die-attaching area and the slot, wherein the bottom surface includes a bottom molding area surrounding the slot, wherein both ends of the slot are located outside the die-attaching area as an input opening and an output opening respectively, the dimension of the input opening is smaller than the one of the output opening;
a chip attached to the die-attaching area to partially cover the slot with the input opening and the output opening exposed;
a plurality of electrical connecting components electrically connecting the chip to the substrate by passing through the slot; and
an encapsulant having a top molding portion and a bottom molding portion, wherein the top molding portion is formed on the top molding area and the bottom molding on the bottom molding area and inside the slot so that the top molding portion and the bottom molding portion are connected at the input opening and at the output opening, wherein the volume of the top molding portion is larger than the one of the bottom molding portion.

2. The semiconductor package as claimed in claim 1, wherein the slot is off-center designed so that the center of the slot is not aligned with the center of the die-attaching area.

3. The semiconductor package as claimed in claim 2, wherein the center of the die-attaching area is aligned with the center of the substrate.

4. The semiconductor package as claimed in claim 1, wherein the bottom molding portion encapsulates the electrical connecting components.

5. The semiconductor package as claimed in claim 4, wherein the top molding portion encapsulates the chip.

6. The semiconductor package as claimed in claim 1, wherein the substrate has a molding gate formed on the top surface adjacent to the input opening.

7. The semiconductor package as claimed in claim 1, wherein the shape of the input opening is an arc equal or smaller than a half-circle.

8. The semiconductor package as claimed in claim 7, wherein the shape of the output opening includes a half-circle.

9. The semiconductor package as claimed in claim 1, wherein the substrate has a plurality of external pads disposed on the bottom surface outside the bottom molding area.

10. The semiconductor package as claimed in claim 9, further comprising a plurality of external terminals disposed on the external pads.

11. A method of assembling a semiconductor package comprising:
providing a substrate having a top surface, a bottom surface, and at least a slot, wherein the top surface includes a die-attaching area and a top molding area surrounding the die-attaching area and the slot, wherein the bottom surface includes a bottom molding area surrounding the slot, wherein both ends of the slot are located outside the die-attaching area as an input opening and an output opening respectively, the dimension of the input opening is smaller than the one of the output opening;
attaching a chip to the die-attaching area to partially cover the slot with the input opening and the output opening exposed;
forming a plurality of electrical connecting components to electrically connect the chip to the substrate by passing through the slot; and
forming an encapsulant having a top molding portion and a bottom molding portion, wherein the top molding portion is formed on the top molding area and the bottom molding portion on the bottom molding area and inside the slot so that the top molding portion and the bottom molding portion are connected at the input opening and at the output opening, wherein the volume of the top molding portion is larger than the one of the bottom molding portion.

12. The method as claimed in claim 11, wherein the mold-flowing speeds above and below the substrate for forming the encapsulant are balanced and arrive at the output opening at the same time.

13. The method as claimed in claim 11, wherein the slot is off-center designed so that the center of the slot is not aligned with the center of the die-attaching area.

14. The method as claimed in claim 13, wherein the center of the die-attaching area is aligned with the center of the substrate.

15. The method as claimed in claim 11, wherein the bottom molding portion encapsulates the electrical connecting components.

16. The method as claimed in claim 15, wherein the top molding portion encapsulates the chip.

17. The method as claimed in claim 11, wherein the substrate has a molding gate formed on the top surface adjacent to the input opening.

18. The method as claimed in claim 11, wherein the substrate has a plurality of external pads disposed on the bottom surface of the substrate outside the bottom molding area.

19. The method as claimed in claim 18, further comprising the step of disposing a plurality of external terminals on the external pads.
